(19) United States
(12) Patent Application Publication
(10) Pub. No.: US 2012/0244702 A1
(43) Pub. Date: Sep. 27, 2012

(54) METHOD FOR PRINTING A SUBSTRATE

(75) Inventors: Andrea Baccini, Mignagola Di Carbonera (IT); Marco Galiazzo, Padova (pd) (IT)

(73) Assignee: APPLIED MATERIALS ITALIA S.R.L., Treviso (IT)

(21) Appl. No.: 13/302,970

(22) Filed: Nov. 22, 2011

Related U.S. Application Data
(60) Provisional application No. 61/466,408, filed on Mar. 22, 2011.

(51) Int. Cl. H01L 21/768

(52) U.S. Cl. 438/667; 257/E21.597

(57) ABSTRACT

Embodiments of the present invention generally relate to methods of printing MWT solar cells. The methods include positioning the non-light-receiving side of a solar cell substrate on a support. The solar cell substrate has a plurality of holes formed therethrough. The plurality of holes are then metalized. Metalizing the holes includes applying a first silver-containing paste within the holes, or depositing the first silver-containing paste on the interior surface of the holes. The first silver-containing paste is in electrical communication with the front surface and the back surface of the substrate. Then, a plurality of collection fingers are formed on the front surface of the substrate using a second silver-containing paste. The substrate may then be flipped, and one or more printing processes may be performed on the non-light-receiving side of the substrate.

### CROSS-REFERENCE TO RELATED APPLICATIONS

This application claims benefit of U.S. Provisional Patent Application Ser. No. 61/466,408, filed Mar. 22, 2011, which is herein incorporated by reference.

### BACKGROUND OF THE INVENTION

1. Field of the Invention

Embodiments of the present invention generally relate to methods of printing substrates, such as silicon substrates, used in the production of solar cells.

2. Description of the Related Art

Solar cells are photovoltaic devices that convert solar light directly into electric energy. The photovoltaic market has seen a huge expansion over the last ten years, with annual growth rates of greater than 30 percent. Some articles have hypothesized that world energy production from solar cells could exceed 10 GWp in the near future. It has been estimated that more than 95 percent of all solar modules are based on silicon substrates. The high growth rate in the market, combined with the need to substantially reduce the costs of solar electricity, has resulted in a number of challenges for the creation of commercially viable, high-quality solar cells. Some challenges which affect the commercial viability of solar cells include production costs, solar cell performance, and production capacity.

Solar cells typically have one or more p-n junctions. Each p-n junction comprises two different zones inside a semiconductor material, in which one side is identified as the p-type zone and the other as the n-type zone. When the p-n junction of a solar cell is exposed to solar light (consisting of energy deriving from photons), the solar light is converted into electricity by means of the photovoltaic effect. Solar cells generate a specific quantity of electric energy and are stacked in modules sized so as to deliver the desired quantity of system energy. Solar modules are connected in panels with specific frames and connectors. Solar cells are commonly formed from silicon substrates, which can be monocrystalline or multi-crystalline silicon substrates. A typical solar cell comprises a silicon substrate, such as a wafer, having a thickness typically less than about 0.3 mm. The silicon substrate generally has a thin layer of n-type silicon on the top of a p-type zone formed on the substrate.

FIG. 1 schematically illustrates a standard silicon solar cell C formed from a substrate 150. Thin lines or fingers 116 are disposed on the front surface (i.e., the light-receiving surface) of the substrate 150. The thin lines or fingers 116 are parallel to each other, and are adapted to collect the electric current generated by the photovoltaic effect and to supply the electric current to collector bars or contact busbars, such as busbars 114. The busbars 114 are also disposed on the light-receiving surface of the solar cell C, and are positioned perpendicular to and in electrical contact with the fingers 116.

Screen printing has been used in printing designs on objects, such as fabrics or ceramics, and is used in the electronics industry to print models of electric components, such as contacts or electric interconnections, on the surface of a substrate. Methods for making solar cells in the state of the art also use screen printing methods. It is known that the electronic circuits and contacts of solar cells, typically fingers and busbars, are made by means of screen printing processes with suitable conductive or contact pastes. The screen printing occurs in one or more screen printing stations, from and to which each of the cells are moved while supported on a transporter. The transporter has a surface or processing plane on which the solar cells to be processed are positioned during the printing process.

In general, solar cells can be divided into different categories according to their structure, one of which is called “back-contact” solar cells. A back-contact solar cell is a solar cell in which the ohmic contacts for the opposite doped regions of the solar cell are disposed on the back (i.e., non-light-receiving surface) of the solar cell. The presence of contacts on the back surface of the solar cell reduces irradiation losses which would be caused by the presence of metal contacts on the light receiving surface of the solar cell.

One of the methods of producing back-contact solar cells includes Metal Wrap Through (MWT) technology, which positions both external contacts (or busbars) 14 for the oppositely-doped regions on the back surface B, while the collection junctions (or fingers) are positioned on the front surface. The current collected on the front surface F by the collection junctions or fingers is conducted to the back surface B through holes which extend transversely through the substrate. The current is then collected through one or more busbars positioned on the back surface of the solar cell. In this way, losses due to the zones darkened by the front metallization grid are reduced, since busbars are positioned on the non-illuminated surface of the solar cell. The MWT technology is described for example in the application WO-A-98/54763 and in the application EP-A-2.068.369.

Within the framework of the MWT technology, it is known that in typical MVVT formation processes, the printing method is started by operating on the back surface B which faces upward, while the front surface F faces downward and is in contact with a support. FIGS. 2A and 2B illustrate substrates 250A and 250B during a typical MWT printing method, which generally includes three printing steps. In a first printing step, the first substrate 250A is positioned such that the front surface F is facing the support 218. During the first printing step, holes disposed through the first substrate 250A between the front surface F and the back surface B are metalized by applying a paste having either or both of a conductive and contact function to the interior of the holes. Additionally, busbars are also printed during the first printing step using the same paste. The busbars are printed such that they are in electrical contact with the holes. The metal paste M is printed in the desired pattern of the busbar (which includes the openings of the holes) and the paste is drawn into the holes via vacuum suction through the support 218. However, due to the fluidic properties of the metal paste M, the vacuum suction applied to draw the metal paste M into the holes often results in undesired deposits D of the metal paste M on the surface of the support 218.

After the first printing step, the first substrate 250A is flipped (e.g., 180 degrees) so that the back surface B is positioned on the support 218. During the second printing step, with the front surface F facing upward, fingers are printed on the front surface F of the first substrate 250A. Subsequent to the second step, the first substrate 250A is again flipped so that the front surface F faces the support 218, and the back surface of the first substrate 250A is metalized using an aluminum-containing paste. Subsequently, as shown in FIG. 2B, a second substrate 250B is then introduced to the printing station, again with the back surface B facing upward, and is processed similar to the first substrate 250A.

One disadvantage of this three-step method, which can be defined as the “back-front-back” method (with reference to the surfaces which are respectively subjected to screen printing), is that the conductive paste used to metalize the holes often results in contamination of the support 218. This contamination is due both to the effect of gravity and to the effect of suction used to draw the metal paste M into the holes during metallization. Often, gravity and over-suction result in the paste undesirably traveling through the holes and contaminating the support 218. The contamination forms undesired deposits D, which can contaminate the front surface F of the subsequently-processed second substrate 150 when the second substrate 150 is transferred onto the support 218. The contamination results in a poor quality print of the fingers, and consequently, reduces the conversion efficiency of the final manufactured device. Another disadvantage of the “back-front-back” print method is that it is necessary to use the same paste both to fill the holes and also to make the busbars during the first print step.

Therefore, there is a need in the art for printing a substrate having reduced contamination and improved print quality.

The Applicants have devised, tested and embodied the present invention to overcome the shortcomings of the state of the art and to obtain these and other purposes and advantages.

### SUMMARY OF THE INVENTION

Embodiments of the present invention generally relate to methods of printing MVVT solar cells. The methods include positioning the non-light-receiving side of a solar cell substrate on a support. The solar cell substrate has a plurality of holes formed therethrough. The plurality of holes are then metalized. Metalizing the holes includes applying a first silver-containing conductive paste within the holes, or depositing the first silver-containing conductive paste on the interior surfaces of the holes. The first silver-containing conductive paste is in electrical communication with the front surface and the back surface of the substrate. Then, a plurality of collection, fingers are formed on the front surface of the substrate using a second silver-containing paste. The plurality of collection fingers are electrically coupled and extend substantially radially from at least one of the plurality of metalized holes. The substrate may then be flipped, and one or more printing processes may be performed on the back surface of the substrate.

In one embodiment, a method for printing a substrate comprises positioning a substrate on a support within a printing unit. The substrate has a back surface in contact with the support, a front surface opposite the back surface, and a plurality of holes extending between the front surface and the back surface. The holes extending between the front surface of the substrate and the back surface of the substrate are then metalized by applying a first silver-containing paste from the direction of the front surface of the substrate. Metalizing the holes includes filling the holes with the first silver-containing paste or depositing the first silver-containing paste on the interior surfaces of the holes to form an electrical connection between the front surface of the substrate and the back surface of the substrate. A plurality of fingers are then formed on the front surface of the substrate by printing a second silver-containing paste on the front surface of the substrate. The plurality of fingers are in electrical communication with and extend radially from at least one of the holes. The substrate is then flipped and a third paste comprising silver and aluminum is printed on the back surface of the substrate to metalize a plurality of busbars in electrical communication with the holes. The busbars are printed subsequent to metallization of the holes and formation of the plurality of fingers. A fourth paste comprising aluminum is then printed on the back surface of the substrate to metalize the back surface of the substrate.

In another embodiment, the printing operation to form the fingers is performed at least partly before, in order of time, the printing operation to metalize the holes.

In yet another embodiment, the printing operation to form the fingers is performed after, in order of time, the printing operation to metalize the holes.

In yet another embodiment, the printing operation to form the fingers is divided into at least two sub-operations. A first sub-operation includes printing a first layer of the fingers using the second silver-containing contact paste, and a subsequent second sub-operation includes printing a second layer of the fingers on the second silver-containing paste using the first silver-containing paste.

In yet another embodiment, the first sub-operation is performed before, in order of time, the printing operation to metalize the holes. The second sub-operation is performed simultaneously in time and space with the printing operation to metalize the holes, in which the same first silver-containing paste is used to form the fingers and to metalize the holes.

In yet another embodiment, the method includes insulating the front surface metallization from the back surface metallization using a laser scribing technique.

In yet another embodiment, a method for printing a substrate comprises positioning a substrate on a support. The substrate has a back surface in contact with the support and a front surface opposite the back surface. A plurality of fingers are then formed on the front surface of the substrate by printing a first paste comprising silver on the front surface of the substrate. The substrate is then flipped such that the front surface of the substrate is in contact with the substrate support, and a second paste comprising silver and aluminum is printed on the back surface of the substrate to metalize a plurality of busbars.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view of a standard solar cell.

FIGS. 2A and 2B are a schematic views of solar cells during a printing process.

FIG. 3 is a schematic view of a solar cell formed by one embodiment of the invention.

FIG. 4 is a schematic section view of a solar cell formed by an embodiment of the invention.

FIG. 5 is a schematic illustration of a substrate during a printing process according to one embodiment of the invention.

FIG. 6 is a schematic illustration of a substrate during a printing process according to another embodiment of the invention.

FIG. 7 is an isometric schematic view of a processing system.

FIG. 8 is a schematic plan view of the processing system shown in FIG. 7.

FIGS. 9A and 9B are isometric schematic views of a processing nest of the processing system of FIG. 7.

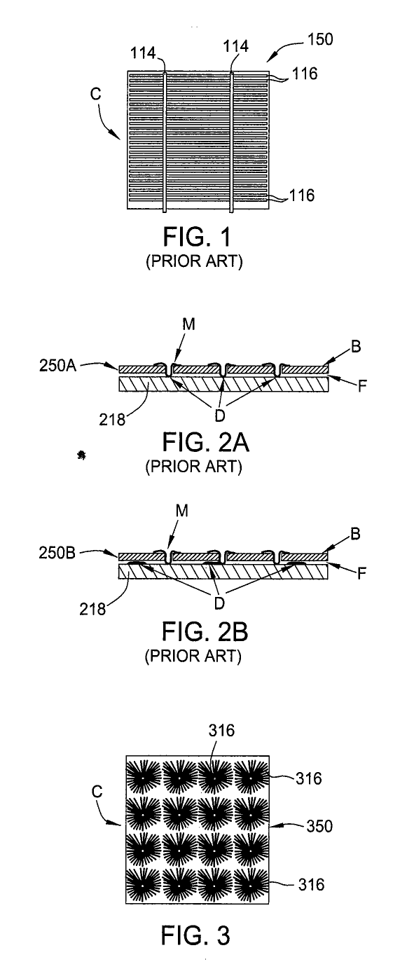

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to methods of printing MWT solar cells. The methods include positioning the non-light-receiving side of a solar cell substrate on a support. The solar cell substrate has a plurality of holes formed therethrough. The plurality of holes are then metalized. Metalizing the holes includes applying a first silver-containing conductive paste within the holes, or depositing the first silver-containing conductive paste on the interior surfaces of the holes. The first silver-containing conductive paste is in electrical communication with the front surface and the back surface of the substrate. Then, a plurality of collection fingers are formed on the front surface of the substrate using a second silver-containing paste. The plurality of collection fingers are electrically coupled and extend substantially radially from at least one of the plurality of metalized holes. The substrate may then be flipped, and one or more printing processes may be performed on the back surface of the substrate.

As used herein, the term “front surface” refers to the surface of the substrate on which, at the end of the process, the fingers are disposed (e.g., the light-receiving surface of a solar cell), and the term “back surface” is the surface opposite the front surface.

Unless otherwise defined, all the technical and scientific terms used here and hereafter have the same meaning as commonly understood by a person with ordinary experience in the technical field to which the present invention belongs. In the event of conflict, the present application, including the definitions, shall prevail. The term “comprise”, and variants of the term such as “comprises” and “comprising”, are used here to indicate the inclusion of a clearly expressed whole, or of clearly expressed wholes, but not the inclusion of any other whole or any other wholes, unless in the context or use an exclusive interpretation of the term is required.

The present invention, which can be defined as “front-front-back-back” with reference to the surfaces that are in turn subjected to screen printing, is an improvement compared to the traditional approach of printing in three steps, because of the reduced number of substrate flipping steps required. Some embodiments of the current invention provide four printing operations, which begin from the front surface of the substrate. Furthermore, in some embodiments of the present invention, a dedicated print paste is used for metallization in the different printing steps performed. This allows for tailoring of the individual print pastes based on the component to be metalized, e.g., the through-holes, the fingers, the busbars, or the backside metallization.

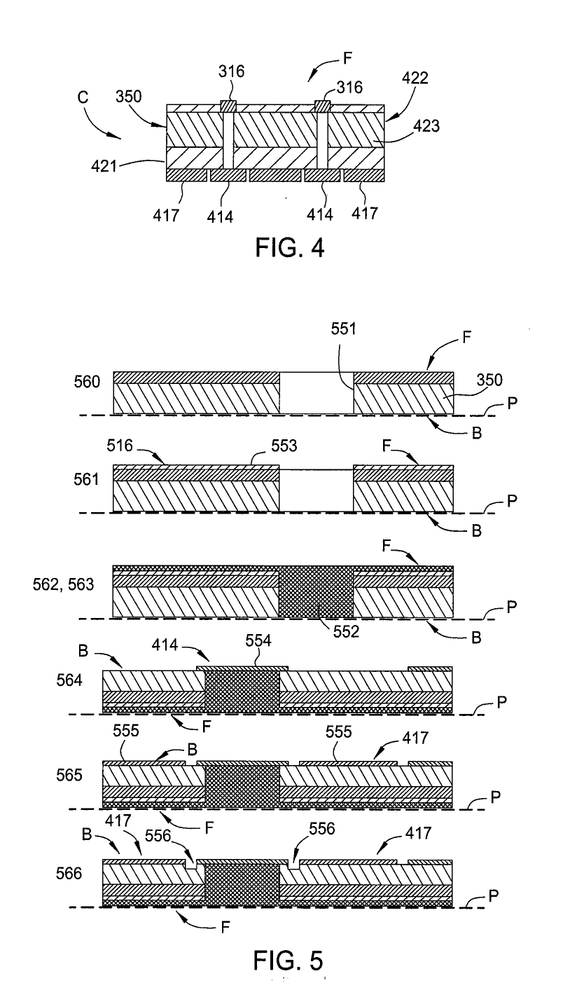

FIG. 3 illustrates a solar cell C which is formed in accordance with an embodiment of the invention. The solar cell C shown in FIG. 3 includes an upper contact structure configured as thin lines or fingers 316 which extend radially on the light receiving side of the solar cell C. Each group of lines or fingers 316 radiates from one or more holes disposed through the solar cell. The lines or fingers 316 collect electric current generated by the photovoltaic effect, and supply the current through the holes to the busbars 414 (shown in FIG. 4) provided on the back surface of the substrate 350 adjacent to the backside metallizations 417.

FIG. 4 illustrates a cross-sectional view of a solar cell formed on a substrate 350 according to embodiments of the invention. The substrate 350 includes a p-type base region 421, an n-type emitter region 422, and a p-n junction region 423 disposed therebetween between. The n-type emitter region 422 is made by doping the substrate 150 with n-type dopants (for example phosphorus (P), arsenic (As), or antimony (Sb)) in order to increase the number of negative charges (i.e., electrons) present within the region. Similarly, the p-type base region 421 is made by adding trivalent atoms to the crystal lattice during a doping process. The addition of trivalent atoms to the crystal lattice results in an electron missing from one of the four normal covalent bonds of the crystal lattice. In this way, the dopant atom can accept an electron from a covalent bond of nearby atoms in order to complete the fourth bond. The acceptance of an electron results in the loss of a half-bond from a nearby atom, causing a “lacuna”.

When light hits the solar cell C, the energy of the photons as they hit generates pairs of electrons-lacunae on both sides of the p-n junction region 423. The electrons spread through the p-n junction to a lower energy level and the lacunae spread in the opposite direction, creating a negative charge on the emitter and a corresponding positive charge in the base. When an electric circuit is formed between the emitter and the base, and the p-n junction is exposed to certain light wavelengths, a current will flow. The electric current generated by the semiconductor flows through the fingers 316 disposed on the front surface (i.e., the light receiving surface), indicated by F, and through to the back surface, indicated by B, of the solar cell C. The solar cell C is generally covered by a thin layer of dielectric material, such as silicon nitride, to function as an anti-reflection coating (ARC), in order to minimize the reflection of the light from the front surface F of the solar cell C.

The fingers 316 are in electrical contact with the substrate 350 and are able to achieve an ohmic connection with one or more doped regions (for example the n-type emitter region 422) of the substrate 350. An ohmic contact is a region on a semiconductor device which has been predisposed so that the current tension curve (I-V) of the device is linear and symmetrical; that is there is no high resistance interface between the doped silicon region and the metal contact. Low resistance and stable contacts are desirable for the performance of solar cells and the reliability of the circuits made in the production process of solar cells. To increase the contact with the solar cell device, the fingers 316 are typically positioned on a highly doped region formed on the substrate surface in order to allow an ohmic contact to be made. Since the highly doped regions, due to their electric properties, tend to block or minimize the quantity of light that can pass through them, it is desirable to make the highly doped regions relatively small in order to minimize the amount of light blocked. However, at the same time, these regions must be large enough to ensure that the fingers 316 can be reliably formed thereon. Highly doped regions can be made on the substrate surface using a variety of patterning techniques to create areas with higher and lower doping, for example by spreading phosphorus using a diffusion barrier according to a pattern. A back contact, such as a backside metallization 417 formed on the back surface B of the substrate 350 completes the electric circuit required to produce current by forming an ohmic contact with the p-type base region of the substrate 350.

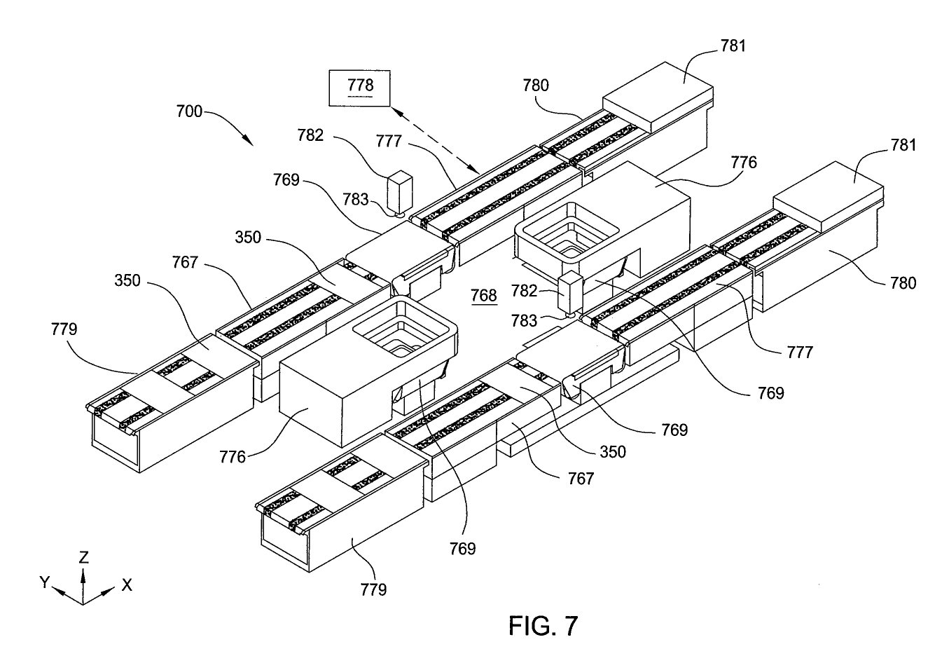

FIG. 5 illustrates a substrate 350 during a printing process according to one embodiment of the invention. In operation 560, a substrate 350, such as a silicon-based wafer having a through-hole 551 extending from the front surface F to the back surface B, is positioned on a processing plane P of a support such as a processing nest 769 (shown in FIG. 7). The substrate 350 is positioned such that a front surface F of the substrate 150 is facing toward a printing means, such as a screen printing device, of a printing station which includes a plurality of printing units. The processing plane P generally has a base of paper or other transpirant material (e.g., a porous material to allow gas flow therethrough), to allow for vacuum suction of the substrate 350. The vacuum suction maintains the substrate 150 in a desired position on the processing plane P, thus improving print quality and precision.

In operation 561, a silver-containing conductive paste 553 is printed on the front surface F of the substrate 350 to metalize a first layer of the collection fingers 516. In operations 562 and 563, a silver-containing conductive paste 552 is used to metalize the holes (operation 563) as well as print a second layer on the collection fingers 516 (operation 562). Thus, the collection fingers 516 are formed using two sub-operations, each of which forms a different layer of the collection fingers 516. The advantage of the dual-layer collection fingers 516 is that the second printing on the collection fingers 516 increases the ratio between height and width (i.e., aspect ratio) of the collection fingers 516. The double-layer collection fingers 516 can be printed having a reduced width while still providing an adequate path for the current travel (e.g., sufficiently low resistivity) due to the increased height of the fingers 516. By forming the collection fingers 516 with a reduced width, the surface area of the light-receiving surface blocked by the collection fingers 516 is thereby reduced.

The present invention utilizes two different pastes (e.g., silver-containing conductive paste 552 and silver-containing conductive paste 553) for printing on the front surface of the substrate, thus allowing each of the silver-containing pastes 552, 553 to have a composition tailored for a specific application. For example, the paste for the metallization of the holes 551 (i.e., silver-containing paste 552) can be selected with suitable viscosity, so as to fill the through-hole or to deposit the paste on the interior surface of the through-hole while avoiding the use of suction. By avoiding the use of suction, the printing process is simplified and the probability of support surface contamination is reduced. In contrast, the silver-containing paste 553 may have a greater viscosity than silver-containing paste 552 in order to prevent “running” of the silver-containing paste 553 when printed on the front surface F of the substrate 350. Furthermore, the silver-containing paste 552 for the holes 551 can also be selected, irrespective of the paste used for the busbars 414 (shown in operation 564), according to a desired value of electric conductivity, while the paste for the busbars can be selected as contact paste. In particular, the desired contact paste based on silver and aluminum for making the busbars facilitates contact, for example, with a current carrying ribbon or wire.

Additionally, although operations 562 and 563 are shown as occurring simultaneously, it is contemplated that holes 551 may be metalized prior to the printing of the second layer of the collection fingers 516, or vice versa.

Subsequent to operations 562 and 563, and prior to operation 564, the substrate 350 is flipped, for example using a robot, and positioned on a second processing plane P of a second printing unit, such that front surface F is disposed on the second process plane P. With the back surface B of the substrate 350 facing a printing means, busbars 414 are printed on the back surface B in electrical contact with the metalized holes 551 using a third conductive paste 554 which includes silver and aluminum.

In operation 565, with the back surface B still facing a printing means, the back surface B is metalized in the regions not covered by the busbars 414 using a fourth aluminum-containing paste 555 to form a backside metallization 471. Thus, substantially the entire back surface B of the substrate 350 is covered by the backside metallization 417 and the busbars 414 except for small gaps or separations therebetween which facilitate electrical isolation thereof. In some embodiments, the method further provides a processing operation 566 by means of which insulation elements 556 are scribed with a laser between the backside metallizations 417 on the back surface of the substrate 350 to form electrical isolation between the back surface metallizations and the busbars 414.

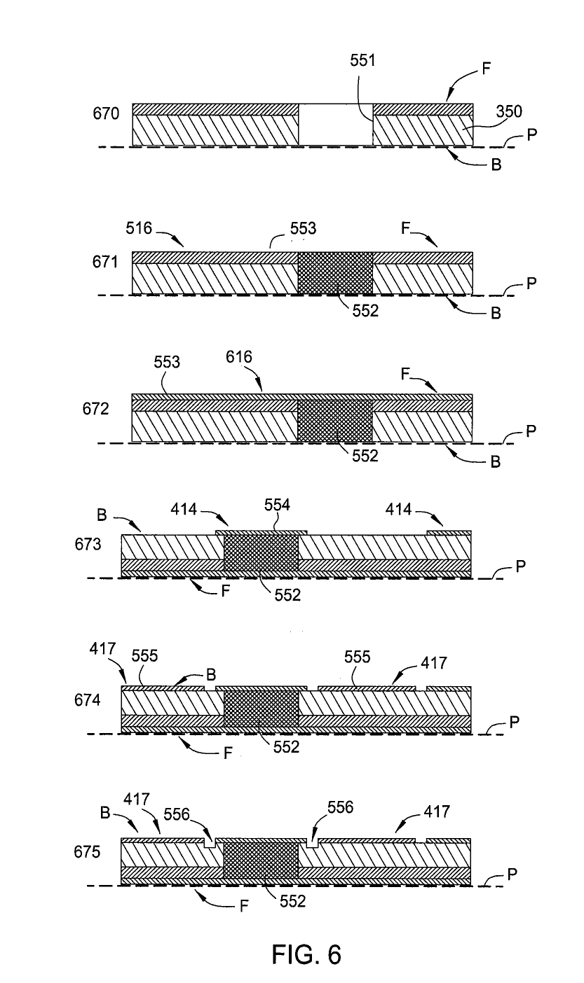

FIG. 6 is a schematic illustration of a substrate during a printing process according to another embodiment of the invention. In operation 670, a substrate 350, such as a monocrystalline silicon substrate having holes 551 extending from a front surface F to a back surface B, is positioned on a processing plane P of a printing unit. In operation 671, a silver-containing conductive paste 552 is printed from the direction of the front surface F of the substrate 350 to metalize the holes 551. The holes 551 may be metalized by filling the holes with the silver-containing conductive paste 552 or by applying the silver-containing conductive paste 552 to the interior surfaces of the holes 551 and leaving an opening therethrough. In operation 672, a silver-containing conductive paste 553 is printed on the front surface F of the substrate 350 to form the metalized collection fingers 616. The metalized collection fingers 616 are in electrical contact with and radiate from the metalized through-hole 551. Although operation 671 is shown as occurring before operation 672, it is contemplated that operation 672 may occur after operation 671. Additionally, in contrast to operations 561, 562, and 563 of FIG. 5, the metalized collection fingers 616 of FIG. 6 contain only a single metal layer printed with a single paste, instead of multi-level collection fingers 516 as described with reference to FIG. 5.

Referring back to FIG. 6, subsequent to operation 672 and prior to operation 673, the substrate 350 is flipped front-surface-down on a second processing plane P of a second printing unit. With the back surface B of the substrate 350 facing a printing means, busbars 414 are printed on the back surface B in electrical contact with the metalized holes 551 using a third conductive paste 554 which includes silver and aluminum.

In operation 674, with the back surface B still facing a printing means, the back surface B is metalized in the regions not covered by the busbars 414 using a fourth aluminum-containing paste 555 to form a backside metallization 417. Thus, substantially the entire back surface B of the substrate 350 is covered by the backside metallization 417 and the busbars 414. However, a small gap is left between the backside metallization 417 and the busbars 414 in order to maintain electrical isolation therebetween. In some embodiments, the method includes operation 675 in which an insulation element 556, such as a groove, is scribed between the backside metallizations 417 on the back surface of the substrate 350 and the busbars 414 to electrically isolate the metallizations from the busbars 414.

With reference to both FIG. 5 and FIG. 6, subsequent to operations 562, 563 (FIG. 5) and operation 672 (FIG. 6), in some embodiments the substrate 350 is positioned on a second processing plane while being flipped in order to accommodate a second substrate 350 on the initial processing plane P. The back surface B of the second substrate 350 is positioned on the initial processing plane P, thus allowing the process cycle to proceed more quickly.

FIG. 7 is a schematic isometric view of a substrate processing system 700 in which substrates may be processed according to methods of the present invention. The system 700 includes two incoming conveyors 767, an actuator assembly 768, a plurality of processing nests 769, a plurality of processing heads 776, two outgoing conveyors 777, and a system controller 778. The incoming conveyors 767 are configured in a parallel processing configuration so that each can receive unprocessed substrates 350 from an input device, such as an input conveyor 779, and transfer each unprocessed substrate 350 to a processing nest 769 coupled to the actuator assembly 768. Additionally, the outgoing conveyors 777 are configured in parallel so that each can receive a processed substrate 350 from a processing nest 769 and transfer each processed substrate 350 to a substrate removal device, such as an exit conveyor 780. Each exit conveyor 780 is adapted to transport processed substrates 350 through an oven 781 to cure material deposited on the substrate 350 via the processing heads 776.

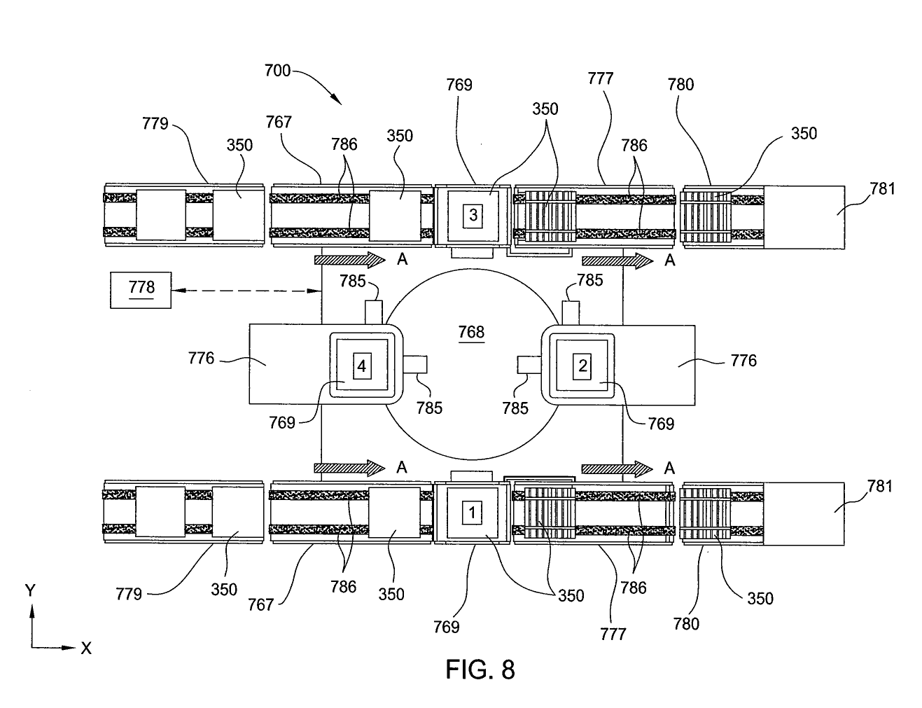

The system 700 also includes an inspection system 782, which is adapted to locate and inspect the substrates 350 before and after processing. The inspection system 782 includes one or more cameras 783 that are positioned to inspect a substrate 350 positioned in the loading/unloading positions “1” and “3,” as shown in FIGS. 7 and 8. The inspection system 782 generally includes at least one camera 783 (e.g., a CCD camera) and other electronic components that are able to locate, inspect, and communicate the results to the system controller 778. In one example, the inspection system 782 is adapted to locate the position of certain features of an incoming substrate 350, and communicate the inspection results to the system controller 778 for analysis of the orientation and position of the substrate 350. The system controller 778 can then determine the positioning of the substrate 350 under a processing head 776 prior to processing the substrate 350. In another example, the inspection system 782 inspects the substrates 350 so that damaged substrates 350 can be removed from the production line. Additionally, it is contemplated that the processing nests 769 may each contain a lamp, or other similar optical radiation device, to illuminate the substrate 350 positioned thereon so that it can be more easily inspected by the inspection system 782.

The system 700 is a screen printing processing system and the processing heads 776 include screen printing components which are configured to screen print a patterned layer of material (such as a conductive paste) on a substrate 350. In the case of screen printing, the processing heads 776 are used to print different pastes, including pastes 552, 553, 554 and 555 (shown in FIG. 5), on the front surface F and back surface B of the substrate 350. Alternatively, it is contemplated that the system 700 may be an ink jet printing system and the processing heads 776 include ink jet printing components, which are configured to deposit a patterned layer of material on a substrate 350.

FIG. 8 is a schematic plan view of the system 700 depicted in FIG. 7. FIG. 8 illustrates the system 700 having two processing nests 769 (in positions “1” and “3”) each positioned to both transfer a processed substrate 350 to the outgoing conveyor 777 and to receive an unprocessed substrate 350 from the incoming conveyor 767. Thus, in the system 700, the substrate motion generally follows the path “A” shown in FIGS. 7 and 8. In this configuration, each of the other two processing nests 769 (in positions “2” and “4”) are positioned under a processing head 776 so that a process (e.g., screen printing or ink jet printing) can be performed on the unprocessed substrates 350 situated on the respective processing nests 769. The parallel processing configuration of system 700 allows for increased processing capacity with a minimized processing system footprint. Although the system 700 is depicted as having two processing heads 776 and four processing nests 769, it is contemplated that the system 700 may comprise additional processing heads 776 and/or processing nests 769 without departing from the scope of the present invention.

The two heads 776 utilized in the system 700 are conventional screen printing heads available from Applied Materials Italia S.r.I. which are adapted to deposit material in a desired pattern on the surface of a substrate 350 disposed on a processing nest 769 in position “2” or “4” during a screen printing process. However, it is contemplated that other nests or other supports may also be used to practice embodiments of the invention described herein. The processing head 776 includes a plurality of actuators 785 (for example, stepper motors or servomotors) that are in communication with the system controller 778. The actuators 785 are used to adjust the position and/or angular orientation of a screen printing mask (not shown) with respect to the substrate 350 disposed within the processing head 776. The screen printing mask is generally a metal sheet or plate with a plurality of holes, slots, or other apertures formed therethrough to define a pattern and placement of screen printed material on a surface of a substrate 350.

The screen printed material may comprise a conductive ink or paste, a dielectric ink or paste, a dopant gel, an etch gel, one or more mask materials, or other conductive or dielectric materials. In general, the screen printed pattern that is to be deposited on the surface of a substrate 350 is aligned to the substrate 350 in an automated fashion by orienting the screen printing mask using the actuators 785 and information received by the system controller 778 from an inspection system 782. In one embodiment, the processing heads 776 are adapted to deposit a metal containing or dielectric containing material on a solar cell substrate having a width between about 125 mm and 156 mm and a length between about 70 mm and 156 mm.

The incoming conveyor 767 and outgoing conveyor 777 include two belts 786 to support and transport the substrates 350 to a desired position within the system 700 by use of an actuator that is in communication with the system controller 778. While FIGS. 7 and 8 generally illustrate a substrate transferring system with two belts 786, other types of transferring mechanisms may be used to perform the same substrate transferring and positioning functions without varying from the basic scope of the invention. Additionally, it is contemplated that incoming conveyor 767 and the outgoing conveyor may each have one belt, or may have more than two belts.

The system controller 778 facilitates the control and automation of the overall system 700 and may include a central processing unit (CPU), memory, and support circuits (or I/O). The CPU may be one of any form of computer processors that are used in industrial settings for controlling various chamber processes and hardware (e.g., conveyors, detectors, motors, fluid delivery hardware, etc.) and monitoring the system and chamber processes (e.g., substrate position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 778 determines which tasks are performed on a substrate. Desirably, the program is software which is readable by the system controller 778 and which includes code to generate and store at least one of substrate positional information, the sequence of movement of the various controlled components, substrate inspection system information, and any combination thereof.

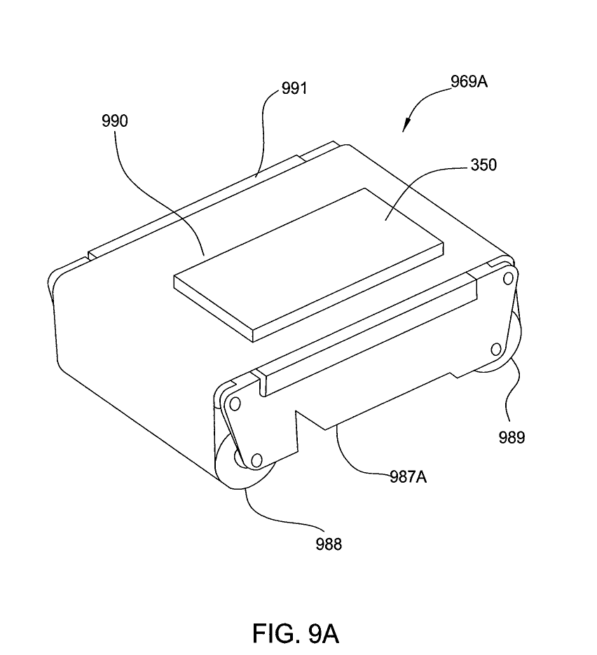

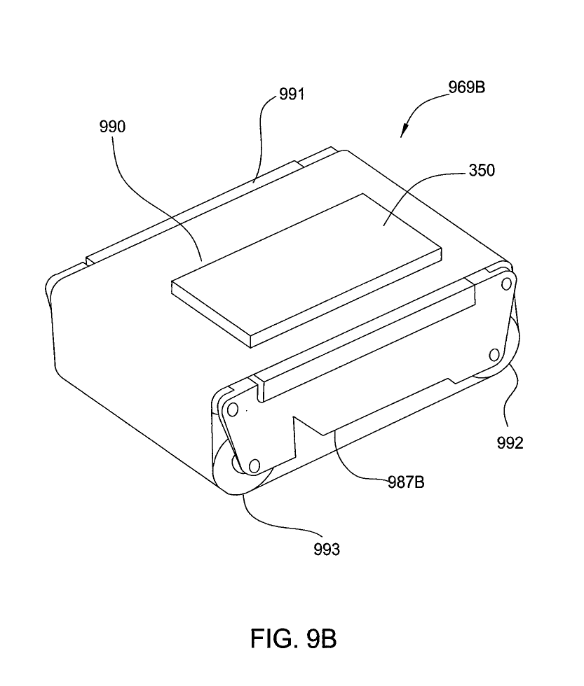

FIGS. 9A-9B are schematic isometric views of processing nests 969A and 969B, which are similar to processing next 769 and can be used in the processing system 700. FIG. 9A illustrates a processing nest 969A having a conveyor 987A which has a feed spool 988 and a take-up spool 989. The feed spool 988 and the take-up spool 989 are adapted to feed and retain a material 990 positioned across a platen 991. The material 990 defines the processing plane P on which the substrate 350 is positioned during processing. The material 990 is a porous material (such as a transpirant material) that permits air or other gases to pass therethrough thus allowing a substrate 350 disposed on one side of the material 990 to be held to the platen 991 by a vacuum generated on the opposing side of the material 990. The vacuum is generally applied by a vacuum pump (not shown) through vacuum ports formed in the platen 991.

FIG. 9B illustrates another embodiment of a processing nest 969B having a continuous conveyor 987B. The conveyor 987B includes a feed roller 992 and an idler roller 993. The feed roller 992 and the idler roller 993 are adapted to feed the material 990 across-the platen 991, as shown in FIG. 9B. It is contemplated that processing nests which have more than one conveyor 987B may contain more than one feed roller 992 and idler roller 993.

The platen 991 has a substrate supporting surface defined by the material 990. The substrate 350 is supported on the material 990 during processing in a processing head, such as processing head 776 shown in FIG. 7. Generally, the material 990 is a porous material that allows a substrate 350, which is disposed on one side of the material 990, to be held to the platen 991 by a vacuum generated on the opposing side of the material 990.

During processing, the processing nests 969A and 969B generally remain in the same orientation when loading and unloading substrates 350. When the processing nests 969A and 969B remain in the same orientation, the continuous conveyor configuration (FIG. 9B) may be preferred over the former conveyor configuration (FIG. 9A), since the former configuration consumes the material 990 as each substrate 350 is loaded and unloaded from the processing nest 969B. Thus, in the conveyor configuration in FIG. 9A, the material 990 is periodically removed and replaced during processing. In contrast, the continuous conveyor configuration (FIG. 9B) does not consume the material 990 during loading and unloading of each substrate 350. Therefore, the continuous conveyor system, as shown in FIG. 9B, may provide cycle time, throughput, and yield benefits in certain embodiments of the present invention.

With the present invention, the problem of contaminating the front surface of a substrate is solved, since the substrate is positioned at the first printing unit of the printing station resting with the back surface of the substrate disposed on the processing plane. The front surface of the substrate is thus preserved from any residual paste inadvertently disposed on the processing plane in prior printing applications. The back surface of the substrate can be disposed on the processing plane initially because the front surface of the substrate can be printed and metalized prior to the back surface, due to the use of multiple paste sources. The multiple paste sources allow the holes to be metalized from the front surface, while the busbars are metalized from the back surface; unlike previous processes which must metalize the holes and the busbars simultaneously (and thus, from the back surface of the substrate).

Although the processing plane may contain some excess paste or other contamination when the substrate is positioned backside-down on the plane for printing, any contamination which may contact the backside is generally negligible. Paste contamination on the backside of the substrate is reduced due to the tailored printing paste compositions, and further, any contamination on the back surface of the substrate does not have as great an effect, since most of the back surface is covered with busbars and backside metallization. Additionally, embodiments of the present invention provide for laser scribing between the busbars and the metallization to reduce or prevent shunting which may occur due to presence of metal paste contamination.

Further benefits of the invention include printing the fingers on the front surface of the substrate in multiple layers. Forming the fingers in multiple levels allows the aspect ratio of the fingers to be increased, thereby reducing shading on the front surface of substrate, while reducing resistivity through the fingers due to the increased finger thickness.

While the foregoing is directed to embodiments of the present invention, other and further embodiments of the invention may be devised without departing from the basic scope thereof, and the scope thereof is determined by the claims that follow.

1. A method for printing a substrate, comprising:
positioning a substrate on a support within a printing unit, the substrate having a back surface in contact with the support, a front surface opposite the back surface, and plurality of holes extending between the front surface and the back surface;
metalizing the holes extending between the front surface of the substrate and the back surface of the substrate by applying a first silver-containing paste from the direction of the front surface of the substrate, wherein metalizing the holes includes filling the holes with the first silver-containing paste or depositing the first silver containing paste on the interior surface of the holes to form an electrical connection between the front surface of the substrate and the back surface of the substrate;
forming a plurality of fingers on the front surface of the substrate by printing a second silver-containing paste on the front surface of the substrate, wherein the plurality of fingers are in electrical communication with and extend radially from at least one of the holes;
flipping the substrate;
printing a third paste comprising silver and aluminum on the back surface of the substrate to metalize a plurality of busbars in electrical communication with the holes, wherein the busbars are printed subsequent to metallization of the holes and forming the plurality of fingers; and
printing a fourth paste comprising aluminum on the back surface of the substrate to metalize the back surface of the substrate.

2. The method of claim 1, wherein the holes are metalized prior to printing the fingers.

3. The method of claim 1, wherein the plurality of fingers are formed prior to metalizing the holes.

4. The method of claim 3, wherein forming the plurality of fingers further comprises printing a layer of the first silver-containing paste over the second silver-containing paste.

5. The method of claim 1, wherein the second silver-containing paste is printed prior to metalizing the holes, and wherein printing the layer of the first silver-containing paste over the second silver-containing paste occurs simultaneously with metalizing the holes.

6. The method of claim 5, further comprising scribing a groove between the busbars and the back surface metallization using a laser.

7. The method of claim 1, further comprising scribing a groove between the busbars and the back surface metallization using a laser.

8. A method for printing a substrate, comprising:
positioning a substrate on a support, the substrate having a back surface in contact with the support and a front surface opposite the back surface;
metalizing plurality of holes extending between the front surface of the substrate and the back surface of the substrate using a first paste;
forming a plurality of fingers on the front surface of the substrate by printing a second paste comprising silver on the front surface of the substrate;
flipping the substrate such that the front surface of the substrate is in contact with the substrate support; and
printing a third paste comprising silver and aluminum on the back surface of the substrate to metalize a plurality of busbars after forming the plurality of fingers on the front surface.

9. The method of claim 8, wherein forming the plurality of fingers further comprises printing the first paste over the second paste.

10. The method of claim 9, further comprising printing a fourth paste comprising aluminum on the back surface of the substrate to metalize the back surface of the substrate.

11. The method of claim 10, further comprising scribing a groove in the back surface using a laser.

12. The method of claim 11, wherein the first paste is a silver-containing paste.

13. The method of claim 8, wherein the holes are metalized prior to forming the plurality of fingers.

14. The method of claim 8, wherein the holes are metalized subsequent to forming the plurality of fingers.
